(19) United States
(12) Patent Application Publication
(10) Pub. No.: US 2020/0064510 A1
(43) Pub. Date: Feb. 27, 2020

(54) Inductive Proximity Switch

(71) Applicant: Pepperl+Fuchs AG, Mannheim (DE)

(72) Inventors: Martin Bachmann, Römerberg (DE); Olaf Huber, Mannheim (DE)

(21) Appl. No.: 16/611,755

(22) PCT Filed: May 8, 2018
(86) PCT No.: PCT/EP2018/061790

§ 371 Date: Nov. 7, 2019

(30) Foreign Application Priority Data
May 8, 2017 (DE) 10 2017 109 813.5

(51) Int. Cl. G01V 3/10; G01V 3/08; H03K 17/95

(52) U.S. Cl. CPC G01V 3/107; H03K 17/9502; H03K 17/9525; G01V 3/081

(57) ABSTRACT

The invention relates to an inductive proximity switch having a primary coil for generating an alternating magnetic field, with an oscillator for driving the primary coil, with a control and evaluation unit, which is operatively connected to the oscillator and is equipped to acquire and evaluate an amplitude and a phase position of a current in the primary coil and for outputting a detection signal depending on the acquired current in the primary coil, with at least one compensation coil for manipulation of the alternating magnetic field generated by the primary coil. The inductive proximity switch is characterized in that a separate controllable current source is present for controlling the at least one compensation coil.

The present invention relates to an inductive proximity switch in accordance with the preamble of claim 1.

A generic proximity switch has the following components: a primary coil for generating an alternating magnetic field, an oscillator for driving the primary coil, a control/evaluation unit, which is operatively connected to the oscillator and is equipped to acquire and evaluate an amplitude and a phase position of a current in the primary coil and for outputting a detection signal depending on the acquired current in the primary coil, and at least one compensation coil for manipulating the alternating magnetic field generated by the primary coil.

A proximity switch with these features is disclosed, for example, in DE 10 2006 053 023 A1. In the case of the proximity switch described there, a transmission coil is connected to the compensation coil in the opposite direction and the transmission coil and compensation coil are operated by a common alternating voltage. The possibilities for influencing the magnetic field in the proximate environment of the proximity switch are therefore limited.

In WO 2014/053240 A2 an inductive proximity switch is described in which case a current, which is induced in a reception coil on the basis of electromagnetic impact by a primary coil, is regulated to zero by feeding compensation currents. The measurement principle consists in querying the compensation currents in order to determine differences in the presence of objects to be detected.

In WO 2012/104086 A2 a metal detector for locating metallic objects is disclosed, in which currents can be regulated to each other in at least two transmission coils such that a received reception coil output signal from at least one reception coil or average values of demodulation phases that are generated from the reception coil output signal, are continuously regulated, even in the presence of a metal target to be detected, similar to WO 2014/053240 A2, to zero.

General effect mechanisms for inductive proximity switches are described in “Firmenschrift ifm electronic; Schulungsunterlagen efector 100—Induktive Sensoren Stand März 2003” [“Company publication ifm electronic; Training documentation efector 100—Inductive Sensors as of March 2003”.

One problem addressed by the invention can be seen in providing a proximity switch in which the alternating magnetic fields can be particularly flexibly influenced.

This problem is solved by the proximity switch with the features of claim 1.

The proximity switch of the of the above-mentioned type is further developed according to the invention by the fact that a separate current source, in particular being independent of the primary coil, is present for controlling the at least one compensation coil.

Advantageous further developments of the proximity switch according to the invention are described in the following description, in particular with reference to the dependent claims and the FIGUREs.

The measurement principle of an inductive proximity switch consists quite generally initially in that a primary coil driven by an oscillator, which can also be designated as a transmission coil, transmits an alternating magnetic field to a monitoring area and that an interaction between this alternating magnetic field and an object to be detected, which can also be designated a target, is measured. One significant effect in the process is that eddy currents and thus, losses arise caused by the alternating magnetic field, draining energy from the oscillator.

In principle, a distance-dependent signal can also be provided with inductive proximity switches. However, because this is extremely sensitively dependent on the precise relative positioning between target and proximity switch, use is made of this only in special situations. As a rule, inductive proximity switches are used as binary (on/off) switching sensors.

In the case of the most common evaluation method, which can be used in particular in the case of the proximity switch according to the invention, the attenuation of the oscillator is evaluated by the approaching target. In so doing, the proximity switch switches when the attenuation through the approaching target becomes so great that the oscillation amplitude falls below a threshold. This can be realized with comparatively simple electronic means.

In the case of an especially preferred embodiment of the inductive proximity switch according to the invention, the control and evaluation unit is equipped to determine when the current in the primary coil falls below a threshold to be specified and depending on that, to output an output signal. In principle, it is also possible to query other functionally monotonically variables related to the current in the primary coil, such as for example the energy content of the primary coil, and to output an output signal, when it falls below a threshold.

Through the existing separate and independently controllable compensation coils according to the invention the quality of the measurement is improved. However, the compensation coils and their independent control are not necessary for the measurement principle as such.

The oscillator for driving the primary coil has as a rule an oscillating circuit and a feedback amplifier. In principle, the primary or transmission coil can also be formed by the inductivity of the oscillating circuit.

In the case of proximity switches in which the basic measurement signal is derived from the attenuation of an oscillator by an approaching target, the primary coil is not a transmission coil in the actual sense. Nevertheless, if a transmission coil is spoken about, it does not mean that a reception coil must be present. In fact, in the case of proximity switches that evaluate an attenuation, there is no reception coil present. Likewise, the use of the expression primary coil does not mean that a secondary coil has to be present. The coils, in the case of which the proximity switches, which evaluate an attenuation, are used for measurement, could be designated more accurately as being measurement or sensor coils.

Those electronic components with which the necessary controls and evaluations are performed are designated as the control and evaluation unit, in particular, thus, the evaluation of the change of the oscillator properties in the case of an approaching target. The control and evaluation unit can be formed by analog and/or digital—electronic components. The components of the control and evaluation unit, which are used to determine the amplitude and phase position of the current in the primary coil, can in the process also be arranged in the oscillator or be parts of the oscillator.

The expression detection signal designates the signal that the proximity switch outputs depending on the approach of a target. In the process, in special cases it can in principle also be an analog, thus distance-dependent signal. As a rule, however, the detection signal is a binary signal, thus an On/Off signal, which indicates whether a target is nearer or farther than a specified switch distance to the proximity switch.

Compensation coils are further coils that can influence the alternate magnetic field generated by the primary coil, but are not constitutive of the actual measurement principle.

The feature that a separate controllable current source should be present means quite generally that the current with which the at least one compensation coil is driven, is not in a fixed, unchangeable and in this sense rigid relationship to the current through the primary coil. This current source should be controllable in the sense that the current through the compensation coil or compensation coils is variably adjustable. It is thus essential that the at least one compensation coil can be controlled completely independently through/by the separate current source.

The invention has realized that, while the rigid linking of the drive of the compensation coils to those of the transmission or primary coil facilitates a rough compensation of the effects for example of a housing or of specified installation materials, these undesirable effects can be significantly better reduced in the case of flexible control of the at least one compensation coil.

One central idea of the invention can be considered that of designing the driving of the at least one compensation coil more flexibly and in particular independent of a feeding of the primary coil and, to this end, providing the suitable technical means in the form of the separately controllable, in particular independently controllable, current source.

One significant advantage of the proximity switch according to the invention can be seen in the fact that, compared to the devices known from the prior art, it is significantly less prone to failure vis-à-vis materials and parts that are in an environment of the proximity switch. In the process, of particular importance is the fact that the proximity switch according to the invention can also be individually adjusted and operated in different installation circumstances.

In especially preferred variants of the proximity switch according to the invention, the controllable current sources are equipped to control an amplitude and a phase position of the respective compensation coil current.

In principle, the main idea of the present invention is realized when a single compensation coil and an associated separately controllable, in particular independently controllable current source are present. The above specified advantages according to the invention are however achieved in special manner in the case of variants where several compensation coils, in particular two compensation coils, are present.

In principle, it is possible that a plurality of compensation coils are operated from one and the same controllable current source. One obtains even more possibilities with respect to the individual adaptation of the inductive proximity switch according to the invention, if a separately controllable, in particular independently controllable, current source is present for each of the compensation coils.

With respect to the specific geometrical design and the specific positioning of the compensation coils relative to the primary coil there is, in principle, freedom of design.

One special advantage of the present invention is expressed herein, because the spatial distributions of the alternate magnetic fields can be particularly well modeled on the basis of this freedom of design.

In the process, cylinder-symmetrical arrangements of the primary coil and the compensation coil or compensation coils have proven particularly advantageous. For example, a compensation coil can surround the primary coil, in particular, completely. There, in particular those arrangements are meant in which the primary coil is arranged on a front side of an essentially tubular housing such that a cylinder axis of the primary coil runs coaxially with an axis of the tubular housing and in which a compensation coil surrounds the thus positioned primary coil radially outward.

A compensation coil surrounding the primary coil is particularly effective when the compensation coil has an expansion in an axial direction which is greater than or equal to an expansion of the primary coil or of a coil core of the primary coil in this axial direction.

Moreover, arrangements in which at least one compensation coil is arranged in an axial direction behind the primary coil have proven to be particularly expedient.

A compensation coil positioned in axial direction behind the primary coil is particularly effective when this compensation coil has a diameter that is greater than or equal to a diameter of the primary coil or of the diameter of a coil core of the primary coil.

In principle, the invention can be realized in the case of inductive proximity switches without coil cores. In particularly expedient variants, however, the primary coil has a coil core for forming the field distribution of the alternating magnetic field and for its amplification. For example, the coil core can be a pot core of a shape known in principle and made of a material known in principle, for example ferrite.

Particularly advantageously, the coil core is a pot core whose shape is adapted to the shape of the compensation coils.

With respect to the housing, in which the inductive proximity switch according to the invention is accommodated, there is freedom of design in principle. However, those variants in which the primary coil is positioned in a tubular housing on a front side have proven to be particularly expedient.

For example, the primary coil, the compensation coils and the controllable current sources can be arranged in a rectangular or cylindrical housing, in particular in a housing in the shape of a circular cylinder.

The influences on the alternating magnetic field emitted from the primary coil are particularly low in the case of such housing geometries.

There is likewise freedom of design with respect to the material of the housing. This can be made of plastic and/or in principle also of metal. One particular advantage of the invention is that with the assistance of the controllable current source for the at least one compensation coil it is possible to react flexibly to different installation circumstances and housing materials.

In the case of further particularly preferred variants of the invention the in particular analog and/or digital control and evaluation unit is also equipped for controlling the controllable current sources. For example, this control can take place in a software-controlled manner.

In this connection it is further preferable if the control and evaluation unit has a programmable logical component, in particular a microcontroller, in particular with analog and digital functionality.

Further properties and advantages of the invention are described in the following with reference to the attached schematic FIGURE. The FIGURE shows the following:

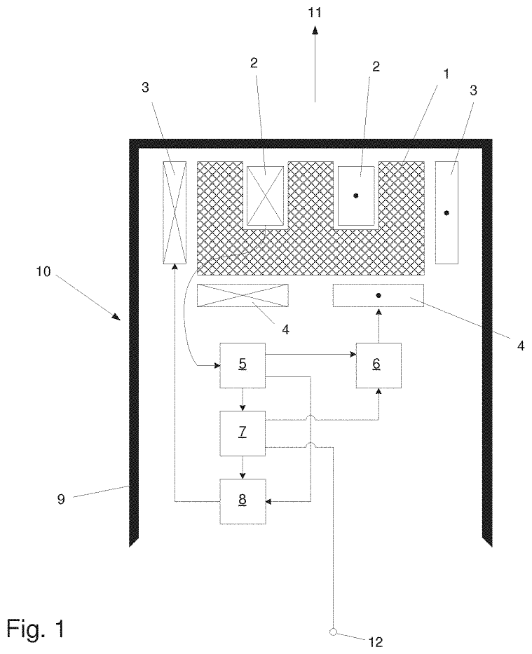

FIG. 1 shows an exemplary embodiment of an inductive proximity switch according to the invention.

The exemplary embodiment schematically represented in FIG. 1 of an inductive proximity switch 10 according to the invention has as essential components a primary coil 2, an oscillator 5, a first compensation coil 3 with an assigned first controllable current source 8 and a second compensation coil 4 with an assigned second current source 6.

These components are accommodated in a housing 9, which can for example be made of plastic and/or of metal.

The primary coil 2, which is used to generate an alternating magnetic field, is accommodated in a pot core 1. Within the housing 9, which for example can have a cubic or cylindrical shape, the pot core 1 is arranged with the primary coil 2 directly at a front side. The alternating magnetic field can thus emerge outwardly. The first compensation coil 3 is located radially outward of the pot core 1 and surrounds it completely in the circumferential direction. In the axial direction, which is labeled reference numeral 11 in FIG. 1, the expansion of the of the first compensation coil 3 is about as large as that of the pot core 1. However, it should be noted that, in principle there is a great freedom of design with regard to the specific geometry and the specific positioning of the compensation coils. For example, the compensation coils do not necessarily have to be formed and positioned flush relative to the primary coil in the manner shown in the FIGURE.

The second compensation coil 4 is a flat coil and, viewed in the axial direction, is located behind the pot core 1. The second compensation coil 4 overlaps essentially the entire rear side of the pot core 1.

Electronic means are provided in the oscillator 5, with which a current can be acquired.

In this respect components of the oscillator 5 and the control and evaluation unit 7 overlap. The oscillator 5 is connected to the control and evaluation unit 7 for evaluation of the current by the primary coil 2.

In the shown exemplary embodiment, the first controllable current source 6 and the second controllable current source 8 are connected to the oscillator 5. This means that, in any event, the frequency of the current through the first compensation coil 3 and the second compensation coil 4 is predetermined by the oscillator 5.

The first controllable current source 8 and the second controllable current source 6 in each case facilitate an individual adjustment of amplitude and relative phase position of the current through the first compensation coil 3 or the second compensation coil 4. These further controls can, for example, as illustrated by corresponding arrows in the present exemplary embodiment, be performed by the control and evaluation unit 7. For example, the control and evaluation unit 7 can be a microcontroller, which can provide analog and digital functionalities. An interface 12 (schematically represented) is available for outputting a preferably binary switching signal, said interface being able to be connected to a bus system.

The compensation coils 3 and 4 are used for local field displacement of the alternating magnetic field generated by the primary coil 2. The electrical variables of the primary coil current, in particular amplitude and phase position, are acquired in the process. The compensation coils 3 and 4, controlled by the controllable current sources 6 and 8, respectively, generate local compensation fields. Due to the possibility of the adjustment of amplitude and phase position in the case of the current sources 6 and 8, respectively, with regard to adjoining installation materials, for example on the housing edge, extremely flexible adaptations are possible. As a special advantage, in the case of the invention, the mentioned installation materials on the edges of the housing, which were acquired without compensation by the primary coil 2, can be especially well hidden and accordingly no longer or only slightly acquired by the evaluation unit 7, without the detection sensitivity of the actual target of interest suffering.

With the present invention a novel inductive proximity switch is provided in which through the basic idea of the individual adaptation of the current of the compensation coils, which takes place in particular independent of a primary current through the transmission coil, significant improvements are achieved with regard to the hiding of objects and materials in the environment of the proximity switch. The reliability of the inductive proximity switch can thus be increased.

### LIST OF REFERENCES

1 Coil core
2 Primary coil
3 Compensation coil
4 Compensation coil
5 Oscillator
6 Controllable current source
7 Control and evaluation unit
8 Controllable current source
9 Housing
10 Inductive proximity switch
11 Axial direction
12 Interface

1-16. (canceled)

17. An inductive proximity switch comprising:
a primary coil for generating an alternating magnetic field,
an oscillator for driving the primary coil,
a control and evaluation unit, which is operatively connected to the oscillator and is equipped to acquire and evaluate an amplitude and a phase position of a current in the primary coil and for outputting a detection signal depending on the acquired current in the primary coil,
at least one compensation coil for manipulating the alternating magnetic field generated by the primary coil,
wherein a separate controllable current source is present for controlling the at least one compensation coil.

18. The inductive proximity switch according to claim 17,
wherein
a plurality of compensation coils are present.

19. The inductive proximity switch according to claim 17,
wherein
a separate controllable current source is present for each of the compensation coils.

20. The inductive proximity switch according to claim 17,
wherein
the controllable current sources are equipped to control at least one of: an amplitude or a phase position of the compensation coil current.

21. The inductive proximity switch according to claim 17,
wherein
a compensation coil surrounds the primary coil at least partially.

22. The inductive proximity switch according to claim 21,
wherein
the compensation coil surrounding the primary coil has an expansion in an axial direction which is greater than or equal to an expansion of the primary coil or of a coil core of the primary coil in its axial direction.

23. The inductive proximity switch according to claim 17,
wherein
a compensation coil surrounds the primary coil completely.

24. The inductive proximity switch according to claim 17,
wherein
a compensation coil is arranged in an axial direction behind the primary coil.

25. The inductive proximity switch according to claim 24,
wherein
the compensation coil arranged behind the primary coil has a diameter that is greater than or equal to a diameter of the primary coil or the diameter of a coil core of the primary coil.

26. The inductive proximity switch according to claim 17,
wherein
the primary coil has a coil core.

27. The inductive proximity switch according to claim 26,
wherein
the coil core is a pot core.

28. The inductive proximity switch according to claim 17,
wherein
the primary coil is positioned in a tubular housing on a front side.

29. The inductive proximity switch according to claim 17,
wherein
the primary coil, the compensation coils and the controllable current sources are arranged in a rectangular or cylindrical housing.

30. The inductive proximity switch according to claim 29,
wherein
the housing is made of at least one of plastic or metal.

31. The inductive proximity switch according to claim 17,
wherein
the primary coil, the compensation coils and the controllable current sources are arranged in a housing in the shape of a circular cylinder.

32. The inductive proximity switch according to claim 17,
wherein
the control and evaluation unit is also equipped to control the controllable current sources.

33. The inductive proximity switch according to claim 32,
wherein
the control and evaluation unit has a programmable logical component with analog and digital functionality.

34. The inductive proximity switch according to claim 32,
wherein
the control and evaluation unit has a programmable microcontroller with analog and digital functionality.

35. The inductive proximity switch according to claim 17,
wherein
the control and evaluation unit is equipped to determine when the current in the primary coil falls below a threshold to be specified and depending on that, to output an output signal.
